(19) United States
(12) Patent Application Publication
(10) Pub. No.: US 2023/0343832 A1
(43) Pub. Date: Oct. 26, 2023

(54) Heterojunction-Based Vacuum Field Effect Transistors

(71) Applicant: Government of the United States, as represented by the Secretary of the Air Force, Wright-Patterson AFB, OH (US)

(72) Inventors: Marc Cahay, Mason, OH (US); Nathaniel Hernandez, Batavia, OH (US); Harris Hall, Yellow Springs, OH (US); Tyson Back, Dayton, OH (US); Jonathan O'Mara, Moraine, OH (US); Jonathan Ludwick, Loveland, OH (US)

(21) Appl. No.: 18/305,403

(22) Filed: Apr. 24, 2023

Related U.S. Application Data
(60) Provisional application No. 63/497,240, filed on Apr. 20, 2023.
(60) Provisional application No. 63/363,586, filed on Apr. 26, 2022.

(51) Int. Cl. H01L 29/20; H01L 29/778; H01L 29/417

(52) U.S. Cl. CPC H01L 29/2003; H01L 29/7786; H01L 29/41766

(57) ABSTRACT

A transistor comprising a first layer comprising a first material; a second layer comprising a second material applied directly onto the first layer, the first layer of the first material and the second layer of the second material forming a first heterojunction; a first 2-dimensional gas (2DEG) layer in the first layer adjacent the first heterojunction, a plane of the 2DEG layer being parallel to the first heterojunction; a source electrode and a drain electrode fixed on the second layer opposite the first layer; a nanogap between the source electrode and the drain electrode, the nanogap extending through the first layer and at least partially through the second layer beyond the plane of the 2DEG layer, the nanogap arranged perpendicular to the heterojunction; and one or more gates arranged adjacent the source electrode. The nanogap is between about 30-50 nm in width.

### RIGHTS OF THE GOVERNMENT

The invention described herein may be manufactured and used by or for the Government of the United States for all governmental purposes without the payment of any royalty.

Pursuant to 37 C.F.R. § 1.78(a)(4), this application claims the benefit of and priority to prior filed co-pending Provisional Application Ser. No. 63/363,586, filed 26 Apr. 2022, and prior filed co-pending Provisional Application Ser. No. 63/497,240, filed 20 Apr. 2023, which are expressly incorporated herein by reference.

### FIELD OF THE INVENTION

The present invention relates generally to field effect transistors (FETs) and, more particularly, to vacuum field effect transistors (VacFETs) with nanoscale feature sizes.

### BACKGROUND OF THE INVENTION

Previously, gate-insulated vacuum channel devices have been demonstrated that combined the high-frequency switching of vacuum channels with the integration and computational capacity of integrated solid-state devices. The devices fabricated did not require special vacuum packaging, i.e., they operated at atmospheric pressure. More recently, the high-field necessary for field emissions (FE) at low voltage was achieved by creating short emitter-collector gaps via electron beam lithography with an n-doped Si device layer fabricated on a silicon-on-insulator substrate. By designing the relative sharpness of each Si emitter tip, the FE devices demonstrated asymmetric I-V (current-voltage) characteristics, an important feature for replicating the rectification behavior of existing solid-state devices. The FE properties of SiC nanoemitters were studied under different cathode-anode gaps with the aid of focused ion beam etching to control the gap precisely. Controlled etching allowed for systematic variation of the anode-cathode gap distance from 120 nm down to 20 nm; the turn-on voltage for FE was 3.2 V for a gap of 20 nm, and a current of 22.3 nA was achieved at 5 V, which is useful for applications in low-power vacuum devices. A low voltage FET was fabricated with a vertical vacuum channel of length about 20 nm etched into a metal-oxide-semiconductor substrate. That device exhibited a measured transconductance of 20 nS/μm, and on/off ratio of 500 and a turn on voltage of 0.5 V under ambient conditions. Coulombic repulsion in the two-dimensional electron gas (2DEG) at the interface between the oxide and the semiconductor reduces the energy barrier to electron emission, leading to a high emission current density (105 A/cm²) under a bias of only 1 V.

The III-nitride semiconductors have many attractive properties for FE vacuum electronics, including high thermal and chemical stability, low electron affinity, and high breakdown electric field strength. Gallium Nitride (GaN)-based nanoscale vacuum electron diodes are operable in air, with record ultralow turn-on voltages down to 0.24 V and stable high FE currents up to several microamps for single-emitter devices.

An Al_{0.25}Ga_{0.75}N/GaN based lateral VacFET was reported with a nanometer scale void channel. In that device, a 45 nm void channel was formed by etching out the SiO₂ sacrificial dielectric layer between the semiconductor emitter and the metal collector. Under an atmospheric environment instead of vacuum conditions, the GaN based FE device exhibited a low turn-on voltage of 2.3 V and an emission current of 40 μA at a collector bias Vc=3 V, and a low reverse leakage of 3 nA at Vc=3 V. This corresponds to a fairly low line current density 0.23 mA/mm making these devices impractical for high power applications. The observed FE characteristics of their devices was attributed to the nanometer scale void channel as well as the high density 2DEG in the AlGaN/GaN heterojunction. The proximity of the anode across the nanovoid leads to a large enhancement factor at the edge of the GaN/nanovoid interface leading to substantial FE across the nanovoid. The observed low line current density is due to the high work function of the metallic collector which increases the overall barrier height to electron tunneling across the nanovoid.

Vacuum electronics have recently regained interest following proposals for vacuum field effect transistors (VacFETs) with nanoscale feature sizes. Compared to traditional silicon-based transistors, VacFETs offer advantages in terms of electron velocity, fast switching speed, extreme operating temperatures, and radiation hardness. To offer an alternative to solid-state electronics, nanoscale vacuum channel devices need to be fabricated using scalable circuit manufacturing techniques. One must also compare their turn-on voltage and transconductance characteristics with conventional semiconductor devices. Ideally, a vacuum channel device should have large drive currents at low drive voltages; this characteristic requires a low turn-on voltage. Towards that goal, one may either engineer the work function of the emitter, gate, and collector, and/or fabricate devices with an emitter tip with a small radius of curvature in order to enhance the electric field at the cathode. Alternatively, reducing the gap between the emitter and collector will also lead to an increase in the electric field for a fixed voltage or reduce the needed drive voltage for a fixed FE current. More importantly, shrinking device dimensions below 200 nm allows FE devices to operate at atmospheric pressure since the mean free path of electrons at these pressures exceeds this distance.

What is needed is a VacFET having line current density, cutoff frequency, and transconductance levels that are much higher than known devices. The novel and inventive VacFETs presented exhibit line current density and transconductance levels that can reach values of several hundreds mA/mm and tens of mS/mm, respectively, features desirables for high frequency and high power performance.

### SUMMARY OF THE INVENTION

The present invention overcomes the foregoing problems and other shortcomings, drawbacks, and challenges of vacuum electronics. While the invention will be described in connection with certain embodiments, it will be understood that the invention is not limited to these embodiments. To the contrary, this invention includes all alternatives, modifications, and equivalents as may be included within the spirit and scope of the present invention.

According to one embodiment of the present invention a transistor comprises a first layer comprising a first material; a second layer comprising a second material applied directly onto the first layer, the first layer of the first material and the second layer of the second material forming a first heterojunction; a first 2-dimensional gas (2DEG) layer in the first layer adjacent the first heterojunction, a plane of the 2DEG layer being parallel to the first heterojunction; a source electrode and a drain electrode fixed on the second layer opposite the first layer; a nanogap between the source electrode and the drain electrode, the nanogap extending through the first layer and at least partially through the second layer beyond the plane of the 2DEG layer, the nanogap arranged perpendicular to the heterojunction; and one or more gates arranged adjacent the source electrode.

According toa second embodiment of the present invention, a transistor further comprises a first layer comprising a first material; a second layer comprising a second material applied directly onto the first layer, the first layer of the first material and the second layer of the second material forming a first heterojunction; a first 2-dimensional gas (2DEG) layer in the first layer adjacent the first heterojunction, a plane of the 2DEG layer being parallel to the first heterojunction; a third layer comprising the first material; a fourth layer comprising the second material applied directly onto the third layer, the third layer of the first material and the fourth layer of the second material forming a second heterojunction; a second 2-dimensional gas (2DEG) layer in the third layer adjacent the second heterojunction, a plane of the 2DEG layer being parallel to the second heterojunction; a source electrode and a drain electrode fixed on the fourth layer opposite the third layer; a nanogap between the source electrode and the drain electrode, the nanogap extending from the fourth layer into each layer and beyond the plane of each 2DEG layer, the nanogap arranged perpendicular to the first and second heterojunctions; and one or more gates arranged adjacent the source electrode.

According to a third embodiment of the present invention, a transistor comprises a first layer comprising a first material; a second layer comprising a second material applied directly onto the first layer, the first layer of the first material and the second layer of the second material forming a first heterojunction; a first 2-dimensional gas (2DEG) layer in the first layer adjacent the first heterojunction, a plane of the 2DEG layer being parallel to the first heterojunction; a third layer comprising the first material or a third material which is different from the first and second materials; a fourth layer comprising the second material or a fourth material which is different from the first, second, and third materials applied directly onto the third layer, the third layer of the first material and the fourth layer of the second material forming a second heterojunction; a second 2-dimensional gas (2DEG) layer in the third layer adjacent the second heterojunction, a plane of the 2DEG layer being parallel to the second heterojunction; a source electrode and a drain electrode fixed on the fourth layer opposite the third layer; a nanogap between the source electrode and the drain electrode, the nanogap extending from the fourth layer into each layer and beyond the plane of each 2DEG layer, the nanogap arranged perpendicular to the first and second heterojunctions; and one or more gates arranged adjacent the source electrode.

Each of the following features and attributes may be applied as desired to any of the embodiments described herein, in any combination desired.

The nanogap may be between about 30-50 nm in width.

The one or more gates may be top gates, and the nanogap may be formed on one of a drain side and a source side of the one or more top gates. In the alternative, the one or more gates are side gates.

The first material is Gallium Nitride (GaN) and the second material is (Aluminum Gallium Nitride) AlGaN.

The first and second materials are different and are selected from the list consisting of diamond, SiC (Silicon carbide), BN (Boron Nitride), AlP (Aluminum Phosphide), AlAs (Aluminum Arsenide), GaP (Gallium Phosphide), CdS (Cadmium Sulfide), CdSe (Cadmium Selenide), CdTe (Cadmium Telluride), ZnO (Zinc Oxide), ZnSe (Zinc Selenide), ZnS (Zinc Sulfide), ZnTe (Zinc Telluride), GaSe (Gallium Selenide), β-phase GaO (β-phase Gallium Oxide), and a wide variety of ultrawide bandgap binary and ternary oxides, including aluminum gallium nitride alloys (AlₓGa₁₋ₓN), Indium Gallium Nitride (InₓGa₁₋ₓN), β-phase gallium oxide (β-Ga₂O₃), SnO₂, r-GeO₂, ZnGa₂O₄, MgGa₂O₄, BaSnO₃, SrSnO₃, (La_{0.75}Sr_{0.25})CrO₃, AlₓSc₍₁₋ₓ₎N, Ba₂BiTaO₆, CuBO₂, and (Ir_{0.4}Ga_{0.6})₂O₃. The alternating stacks of materials may be any material stack that provides the desired functionality.

The claimed, described, and illustrated features and materials may be combined in any desired manner to achieve the desired performance characteristics.

Additional objects, advantages, and novel features of the invention will be set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### BRIEF DESCRIPTION OF THE DRAWINGS

The accompanying drawings, which are incorporated in and constitute a part of this specification, illustrate embodiments of the present invention and, together with a general description of the invention given above, and the detailed description of the embodiments given below, serve to explain the principles of the present invention.

In this document, relational terms such as first and second, top and bottom, and the like may be used solely to distinguish one entity or action from another entity or action without necessarily requiring or implying any actual such relationship or order between such entities or actions. The terms “comprises,” “comprising,” “includes,” “including,” “has,” “having,” or any other variations thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises . . . a” does not, without more constraints, preclude the existence of additional identical elements in the process, method, article, or apparatus that comprises the element.

Reference throughout this document to “one embodiment,” “certain embodiments,” “an embodiment,” “implementation(s),” “aspect(s),” or similar terms means that a particular feature, structure, or characteristic described in connection with the embodiment is included in at least one embodiment of the present invention. Thus, the appearances of such phrases or in various places throughout this specification are not necessarily all referring to the same embodiment. Furthermore, the particular features, structures, or characteristics may be combined in any suitable manner in one or more embodiments without limitation.

The term “or” as used herein is to be interpreted as an inclusive or meaning any one or any combination. Therefore, “A, B or C” means “any of the following: A; B; C; A and B; A and C; B and C; A, B and C.” An exception to this definition will occur only when a combination of elements, functions, steps or acts are in some way inherently mutually exclusive. Also, grammatical conjunctions are intended to express any and all disjunctive and conjunctive combinations of conjoined clauses, sentences, words, and the like, unless otherwise stated or clear from the context. Thus, the term “or” should generally be understood to mean “and/or” and so forth.

All documents mentioned herein are hereby incorporated by reference in their entirety. References to items in the singular should be understood to include items in the plural, and vice versa, unless explicitly stated otherwise or clear from the text.

Recitation of ranges of values herein are not intended to be limiting, referring instead individually to any and all values falling within the range, unless otherwise indicated, and each separate value within such a range is incorporated into the specification as if it were individually recited herein. The words “about,” “approximately,” or the like, when accompanying a numerical value, are to be construed as indicating a deviation as would be appreciated by one of ordinary skill in the art to operate satisfactorily for an intended purpose, i.e. +/−10% or +/−5%. Ranges of values and/or numeric values are provided herein as examples only, and do not constitute a limitation on the scope of the described embodiments. The use of any and all examples, or exemplary language (“e.g.,” “such as,” or the like) provided herein, is intended merely to better illuminate the embodiments and does not pose a limitation on the scope of the embodiments. No language in the specification should be construed as indicating any unclaimed element as essential to the practice of the embodiments.

For simplicity and clarity of illustration, reference numerals may be repeated among the figures to indicate corresponding or analogous elements. Numerous details are set forth to provide an understanding of the embodiments described herein. The embodiments may be practiced without these details. In other instances, well-known methods, procedures, and components have not been described in detail to avoid obscuring the embodiments described. The description is not to be considered as limited to the scope of the embodiments described herein.

In the following description, it is understood that terms such as “first,” “second,” “top,” “bottom,” “up,” “down,” “above,” “below,” and the like, are words of convenience and are not to be construed as limiting terms. Also, the terms apparatus and device may be used interchangeably in this text.

FIG. 1 presents a cross-sectional view of AlGaN/GaN VacFET, according to an embodiment of the invention.

FIG. 2 presents an illustration of the spatial dependence of the electrostatic potential in the plane of the 2DEG between the source and drain contacts of a VacFET, according to an embodiment of the invention.

FIG. 3 presents a schematic representation of the energy band diagram in the plane of the 2DEG in the proximity of the nanogap depicted in FIG. 1.

FIG. 4A presents a top view of a VacFET with two in-plane side gates.

FIGS. 4B-4E illustrate enlarged top views of source, drain, and side gate configurations of the VacFET illustrated in FIG. 4A.

FIGS. 5A-5C illustrate various sectional, perspective, and top views of a VacFET having side gates, according to an embodiment of the invention.

FIG. 5D illustrates a sliced 3D angled top down view of a vacuum side-gated VacFET, according to an embodiment of the invention.

FIGS. 6A-6B illustrate top and perspective views of a VacFET having top gates, according to an embodiment of the invention.

FIG. 7 illustrates top views of geometry configurations for the cathode, anode, and side gates, according to an embodiment of the invention, including from top to bottom: Triangular, left/right-triangular (for 2DEG gating), cycloid (Hershey), circular, ellipsoid, and blunt (flat).

FIGS. 8A-8B illustrate sectional views of two superlattice variants.

FIGS. 9A-9C illustrate an embodiment having a top gate located near the nanogap.

FIG. 10A presents a top-down view of a top-gated VacFET with a lateral field emitter array (LFEA) composed of 5 field emitting cathodes and anodes. FIG. 10B presents an enlarged view of the source and drain of the VacFET depicted in FIG. 10A.

It should be understood that the appended drawings are not necessarily to scale, presenting a somewhat simplified representation of various features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity or illustration.

### DETAILED DESCRIPTION OF THE INVENTION

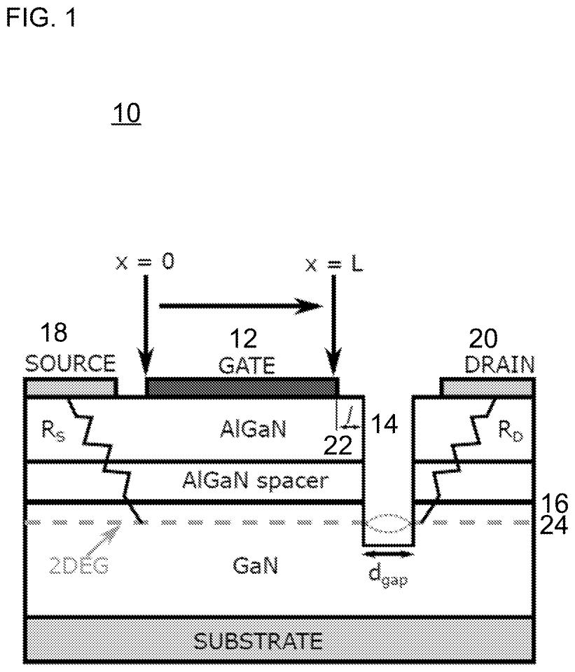

This invention introduces a new class of VacFETs with line current density and transconductance levels much higher than those of recently studied GaN based VacFETs. The new AlGaN/GaN VacFET 10 consists of a modification of a typical HEMT device, as shown schematically in FIG. 1. On the drain side of the gate 12, a nanogap 14 of distance d_{gap} is formed (i.e. formed by either focused ion beam or electron beam (e-beam) photolithography) which is less than 50 nm, e.g. about 30 nm, and with a depth beyond the plane of the 2DEG. Shrinking the nanogap dimension below 200 nm will allow the proposed VacFET to operate at atmospheric pressure since the mean free path of electrons at these pressures exceeds this distance.

The separation 22 between the drain end of the gate and the nanogap (of length 1 in FIG. 1) may be much smaller than the gate length L. This insures better gate control of the barrier height Φ_{eff} across the nanogap. The VacFETs may also be fabricated with the nanogap on the source side of gate 12. Experimentally, the latter arrangement may easily be investigated by simply swapping the roles of the source 18 and drain 20 in FIG. 1.

The following examples illustrate particular properties and advantages of some of the embodiments of the present invention. Furthermore, these are examples of reduction to practice of the present invention and confirmation that the principles described in the present invention are therefore valid but should not be construed as in any way limiting the scope of the invention.

FIG. 1 presents a cross-sectional view of AlGaN/GaN VacFET 10 with a gate 12 of length L. The gate 12 is assumed to be at least ten times larger than the width of the vacuum gap 14 at the end of the gate 12. This ensures a better control of the electron concentration of the 2DEG facing the nanogap at the edge of the gate. The nanogap 14 is etched beyond the plane of the 2DEG 24 near the AlGaN/GaN interface 16 as illustrated in FIG. 1. The current through the 2DEG plane may be modeled using a charge control model the gate 12 and matched to the tunneling current across the nanogap 14. Transport between the source contact 18 and the edge of the 2DEG channel under the gate is modeled using a source resistance R_{S}. Transport from the drain side 20 of the nanogap 14 to the drain contact 20 is modeled using a drain resistance R_{D}. The nanogap 14 is assumed to be a distance 1 22 from the edge of the gate 12 and should be just a few tens of nm which is much smaller than the gate length L. The distance 1 22 should be in the range of a few μm down to 0.5 μm. This is advantageous because VacFETs with smaller gate lengths will be able to operate at a much higher frequency. The Coulomb interaction between the 2DEG plane and holes 26, 27 located near the vacuum interfaces (i.e., where the 2DEG layer 24 meets the nanogap 14) on both sides of the nanogap 14 leads to highly concentrated electric field lines (shown as curved dashed lines) in the nanogap 14 which enhances the tunneling current across it.

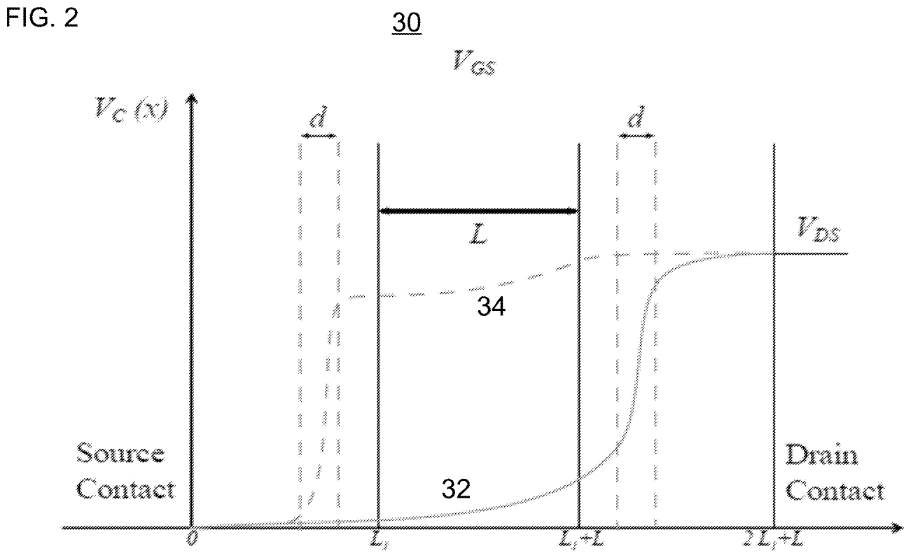

FIG. 2 presents an illustration 30 of the spatial dependence of the electrostatic potential in the plane of the 2DEG between the source and drain contacts of a VacFET with a nanogap 14 on the drain (full line 32) or source (dashed line 34) of a VacFET with a gate 12 of length L and with source 18 and drain 20 contacts a distance L₁ from the edges of the gate 12. The vertical dashed line represents the location of the nanogap 14 of with d_{gap} located either on the source 18 or drain 20 side of the gate. FIG. 1 presents d_{gap} on the drain side.

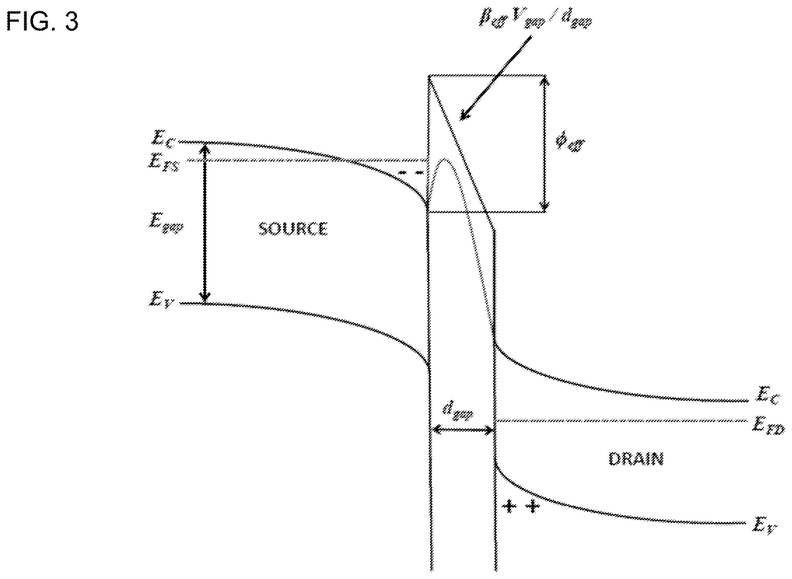

FIG. 3 presents a schematic representation of the energy band diagram in the plane of the 2DEG in the proximity of the nanogap (shown as dashed line 24 in FIG. 1). The lowering of the effective barrier height Φ_{eff} to electrons tunneling across the vacuum gap and the enhancement of the electric field across the channel by a factor β_{eff} result from the Coulomb repulsion between electrons near the gate end/nanogap 14 and the Coulomb attraction from holes piling up on the other side of the nanogap. The potential shown as a red curve also includes the effects of the image charge potentials from both sides of the nanogap. Vgap is the electrostatic potential difference across the nanogap. In the nanogap, there is no effective barrier height for holes since the holes do not tunnel through vacuum. The dashed horizontal blue lines show the location of the Fermi level far into the source 18 (E_{FS}) and drain 20 (E_{FD}) contacts, respectively.

We have shown that the proposed VacFETs threshold voltage strongly depends on which side (source or drain) of the gate the nanogap is located. This may be understood with the help of FIG. 2 which qualitatively presents the spatial dependence of the electrostatic potential V_{c}(x) between the source 18 and drain 20 contacts in the plane of the 2DEG 24. For a given V_{GS}, the VacFET will not conduct until V_{DS} is above a certain threshold because of the resistance of the nanogap 14. Beyond this threshold, a large fraction of V_{D}S will appear across the nanogap 14 and the electrostatic potential V_{c}(x) is expected to have a profile shown as a full 32 (or dashed 34) line when the nanogap is on the drain 20 (or source 18) side of the gate 12. As a result, for the same values of V_{G}S and V_{D}S and the same physical dimensions, the electron concentration will differ in the channel under the gate 12, hence the threshold voltage of the VacFET will be very different when the nanogap is either on the source 18 or drain 20 side. The channel refers to the area directly underneath the top gate, specifically in the 2DEG layer. This tunability makes the proposed VacFETs potential new components for GaN based HEMT technology.

FIG. 3 illustrates the energy profile in the plane of the 2DEG 24 shown as a dashed line in FIG. 1. When a large enough potential is applied to the drain 20, electrons flowing through the 2DEG 24 plane under the gate 12 will have to tunnel through the potential energy barrier present in the vacuum nanogap in the plane of the 2DEG. The actual value of the potential energy barrier in the nanogap is unknown. For a sufficiently narrow nanogap (less than 50 nm in width), the effective barrier height Φ_{eff} is expected to be a few tenths of an electron-volt. This is due to the reduction of the barrier to tunneling electrons due to: (1) the Coulomb repulsion between electrons near the gate end/nanogap interface which helps reduce the barrier height across the nanogap, (2) the effects of the image charge potentials in the nanogap, and (3) the Coulomb attraction from holes piling up on the other side of the nanogap 14. The potential across the nanogap 14 is equal to the potential difference between the electrostatic potential to the right of the gap, V_{c}(L+d_{gap})=V_{DS}−R_{D}I_{DS} (where L is the length of the gate 12 and R_{D} is the internal resistance of the semiconductor region under the drain contact 20, and I_{D}S is the current between the drain and source contacts) plus the potential in the 2DEG plane 24 to the left of the nanogap 14, V_{c}(x=L). The latter must be calculated self-consistently by forcing the current calculated using the charge control model in the 2DEG to be equal to the FE current across the gap. Electrons approaching the anode (drain) region experience Coulombic attraction from the holes formed in that region. This helps the capture of electrons by the anode and increases the effective field enhancement factor at the emission edge of the 2DEG layer 24. The emission edge is where the 2DEG layer meets the nanogap 14. The attraction from the holes on the drain side of the nanogap helps to increase the density of electric field lines in the plane of the 2DEG, which is more beneficial than using three dimensional metallic contacts for which the electric field lines are more spread out. Advantageously, this enhanced focusing of the electric field lines near the nanogap 14 helps to increase the electric field strength across the nanogap and the tunneling current across the nanogap. An e-beam may be used to define a mask that creates the geometry of the emitter/cathode and collector/anode, with the nanogap in between the two.

Additionally, we have developed a semi-analytical model to generate the current-voltage characteristics of the VacFET described above. We have demonstrated that the proposed VacFETs are characterized by line current density and transconductance levels on the order of several hundreds of mA/mm and tens of mS/mm, respectively. With the more complicated design of the e-beam cut (focusing on the geometries of the cathode and anode) to facilitate the flow of electrons in only one direction, the breakdown reverse voltage of the proposed VacFETs may be adjusted, making the device suitable for a variety of wide bandgap CMOS technology, as discussed below.

### Alternative Embodiments

The basic concept outlined above may also work with a wide variety of III-V and II-VI heterostructure materials, including the use of additional dielectric/ferroelectric layers to take advantage of the concept of negative capacitance. Suitable wide bandgap materials which may be used to fabricate the proposed VacFETs include diamond, SiC (Silicon carbide), BN (Boron Nitride), AlP (Aluminum Phosphide), AlAs (Aluminum Arsenide), GaP (Gallium Phosphide), CdS (Cadmium Sulfide), CdSe (Cadmium Selenide), CdTe (Cadmium Telluride), ZnO (Zinc Oxide), ZnSe (Zinc Selenide), ZnS (Zinc Sulfide), ZnTe (Zinc Telluride), GaSe (Gallium Selenide), β-phase GaO (β-phase Gallium Oxide), and a wide variety of ultrawide bandgap binary and ternary oxides, including aluminum gallium nitride alloys (AlₓGa₁₋ₓN), Indium Gallium Nitride (InₓGa₁₋ₓN), β-phase gallium oxide (β-Ga₂O₃), SnO₂, r-GeO₂, ZnGa₂O₄, MgGa₂O₄, BaSnO₃, SrSnO₃, (La_{0.75}Sr_{0.25})CrO₃, AlₓSc₍₁₋ₓ)N, Ba₂BiTaO₆, CuBO₂, and (Ir_{0.4}Ga_{0.6})₂O₃. The use of the dielectric/ferroelectric stack leads to a reduction of the voltage of operation for the proposed negative capacitance (NC)-VacFETs, to increase its ON/OFF current ratio, and to reduce its subthreshold swing while operating at sufficiently low drain voltage. This is desirable because we want low operating voltages that are compatible with CMOS, as well as a low subthreshold swing for better efficiency.

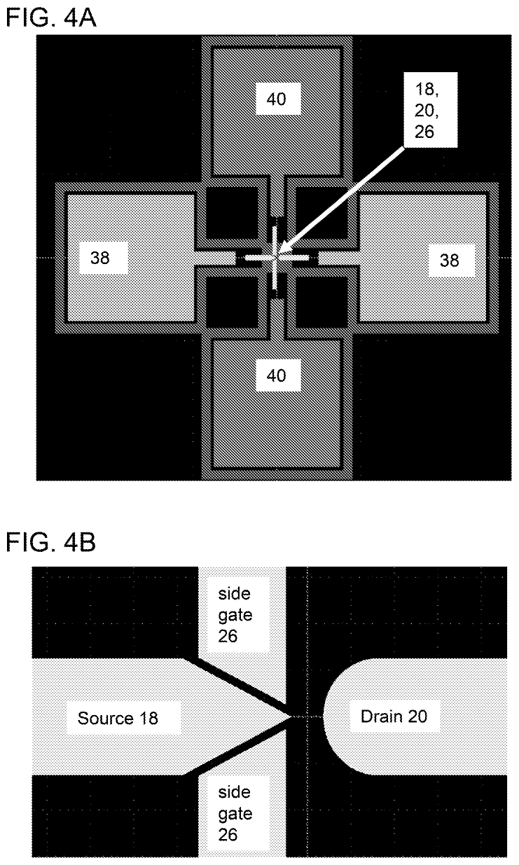

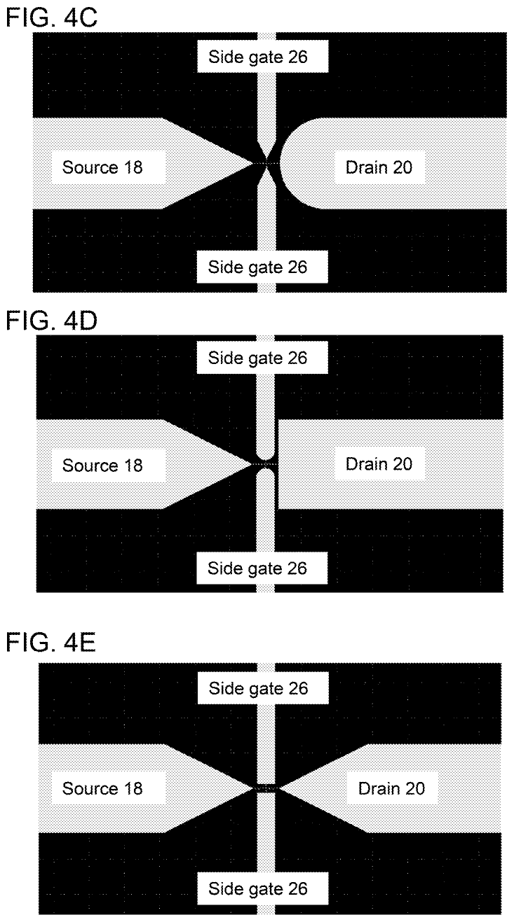

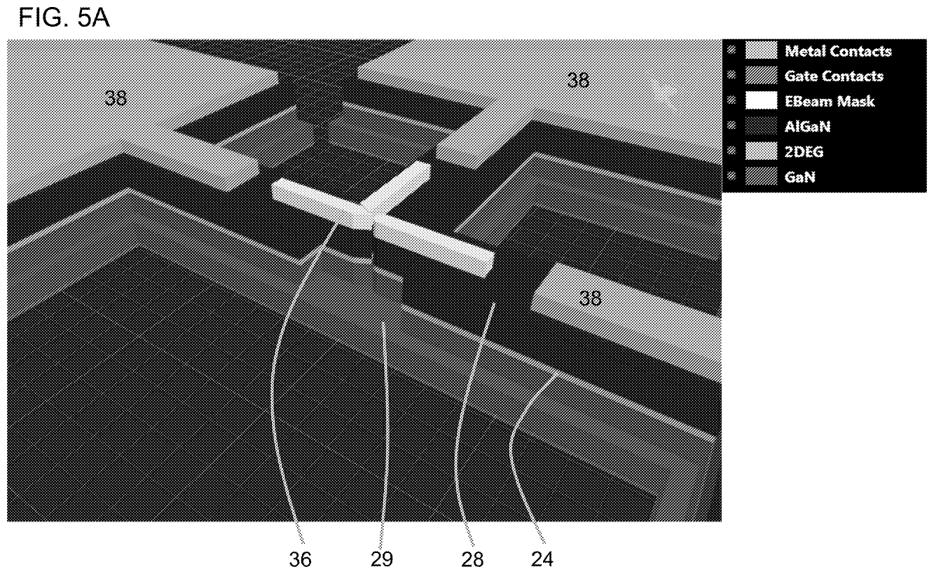

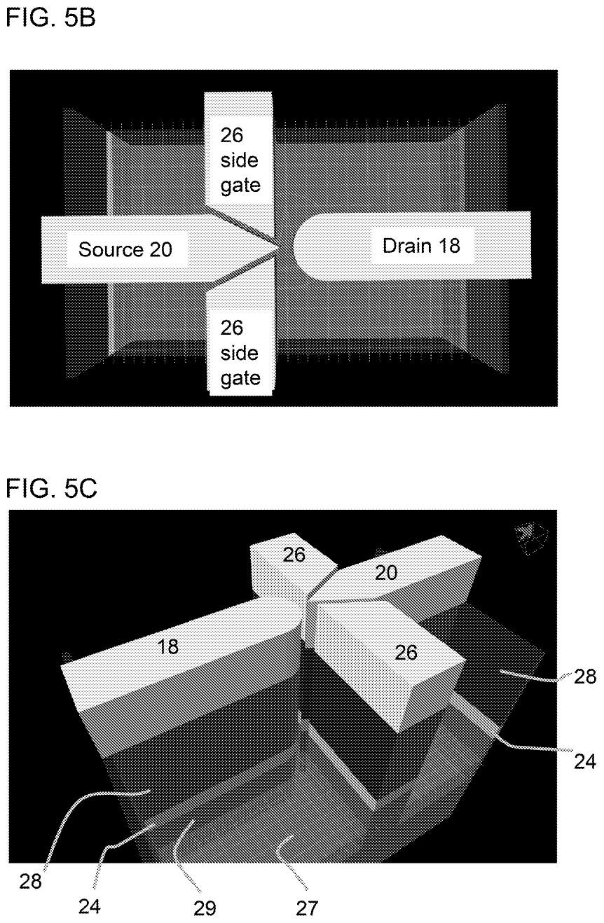

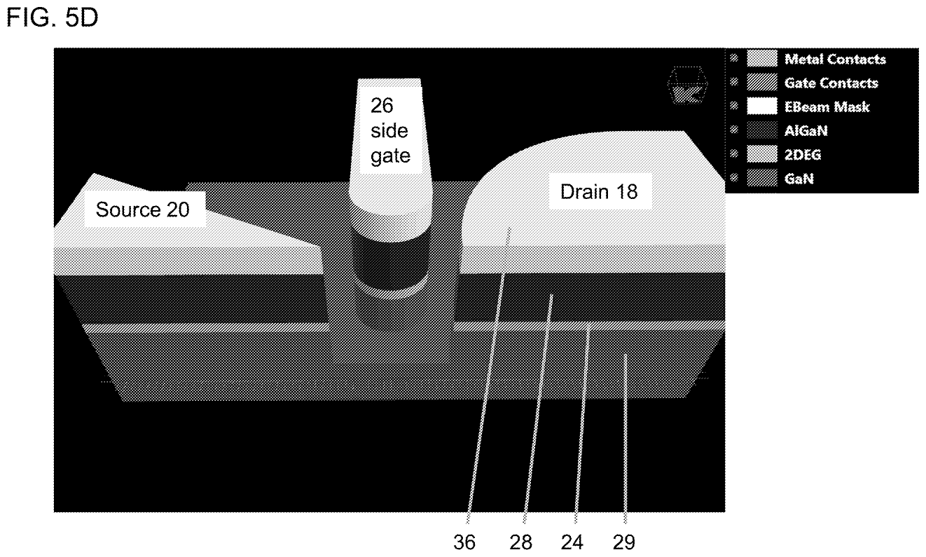

As presented in FIGS. 4A-4E and 5A-5D, the proposed VacFETs may also be fabricated using in-plane side gates 26 instead of the top gates 12 presented in FIG. 1. FIG. 4A presents a top view of a VacFET with two in-plane side gates 26. The side gates 26 may be made triangular in shape near the nanogap, as illustrated in FIGS. 4A-5C and 7. As a result, the side gate electric field enhancement factor will lead to a better electrostatic control of the flow of electrons through the nanogap for smaller values of the applied voltage on the side gates. The contacts 38, 40 are prominent and surround the source 18, drain 20, and side gates 26. Contacts 38 are the metallic contacts to the source 18 and drain 20 regions. Contacts 40 are the Schottky contacts to the side gates 26.

FIG. 413 presents an enlarged top view of source 18, drain 20, and side gates 26 of the VacFET depicted in FIG. 4A. Channel conductivity in the cathode (source) is modulated by the electric field from the 2DEG 24 in two adjacent in-plane side gates 26. The side gates 26 control the tunneling current flowing in the nanogap 14 between the source and drain contacts of the VacFET.

FIG. 5A presents a partial sectional view of a VacFET arrangement omitting a side gate 26 for presentation of the VacFET's construction. The side-gates 26 may provide an alternate means of electrostatic control for the electron concentration in the 2DEG layer 24 in the heterostructures. This allows further tuning of the electron concentration in the 2DEG plane of the VacFET and the flow of electrons across the vacuum gap, i.e., nanogap 14. As presented in FIGS. 5A-5D, an embodiment of a VacFET may include a substrate 27 upon which one or more layers of GaN 29 or other suitable material is formed (see materials listed above). In this example, a 2DEG layer 24 is formed when an AlGaN layer 28 is formed on the GaN layer 29. Other materials (presented above) may be used as well in any suitable combination. An e-beam mask 36 may be formed atop the AlGaN layer 28 in order to precisely define the source 18, drain 20, and side gates 26 during manufacturing in order to form the desired nanogap 14. Other areas of the AlGaN layer 28 may have metal contact layers 38 formed thereon.

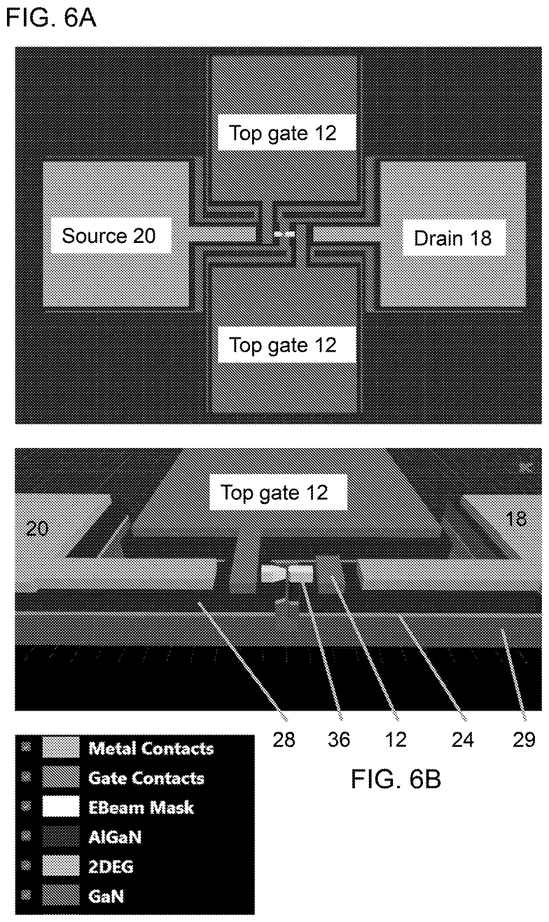

As presented in FIGS. 6A-6B, different geometries (rectangular, triangular, semi-circular) of the e-beam defined nanogap 14 may be used to control the amount of tunneling across the nanogap 14. The geometry of the cathode (source 18) and anode (drain 20) may be designed in order to enhance tunneling through the gap, as presented in FIGS. 6A-6B, without the cathode (source 18) contacting the anode (drain 20), as a result of an increase in the electric field enhancement factor of the cathode. Similar to the arrangement presented in FIGS. 4A-4E, contacts 38 are the metallic contacts to the source 18 and drain 20 regions. Contacts 40 are the Schottky contacts to the side gates 26.

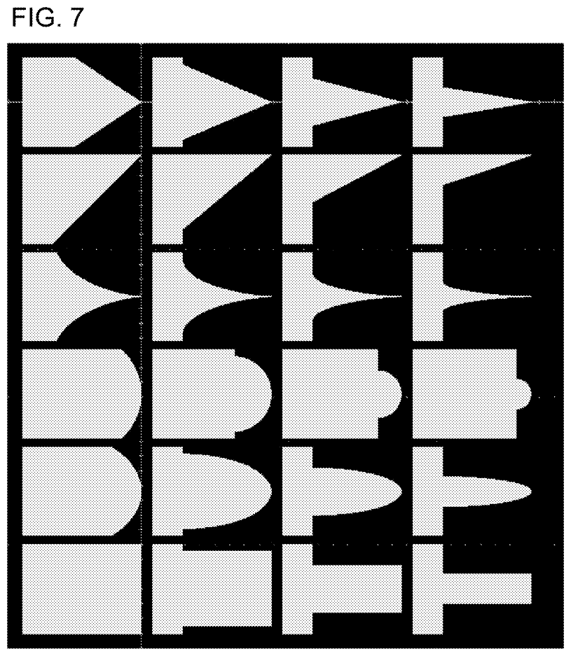

FIG. 7 illustrates top views of geometry configurations for the cathode/source, anode/drain, and side gates, according to an embodiment of the invention, including from top to bottom: Triangular, left/right-triangular (for 2DEG gating), cycloid (Hershey), circular, ellipsoid, and blunt (flat). Each geometry provides distinct performance attributes which may be combined in any manner to achieve the desired performance goals.

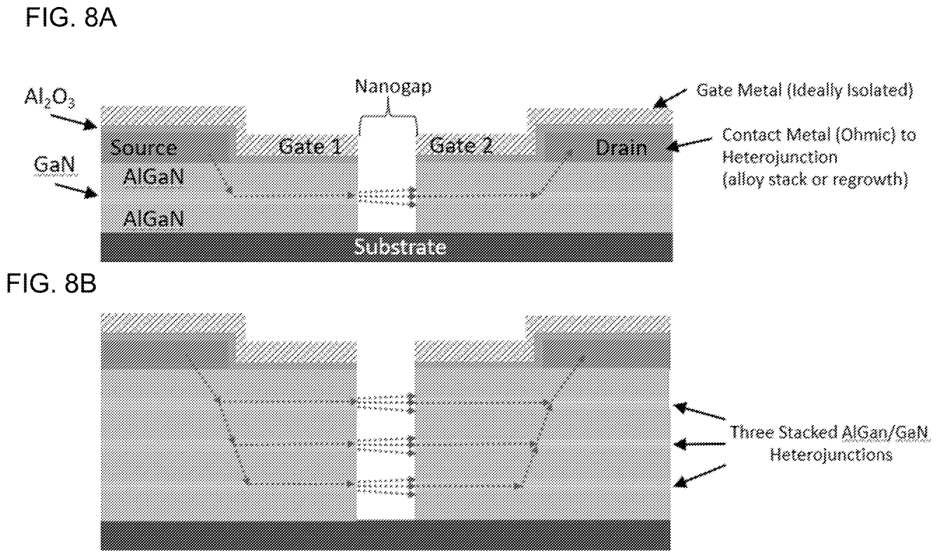

FIGS. 8A-8B illustrate sectional views of two superlattice variants. FIG. 8A illustrates a single heterojunction embodiment having two top gates. FIG. 8B illustrates an embodiment having three stacked heterojunctions, which provides multiple 2DEG layers, and which enables larger current densities. The dashed lines correspond to the current paths for each variant when the conditions are sufficient for vacuum emission across the nanogap.

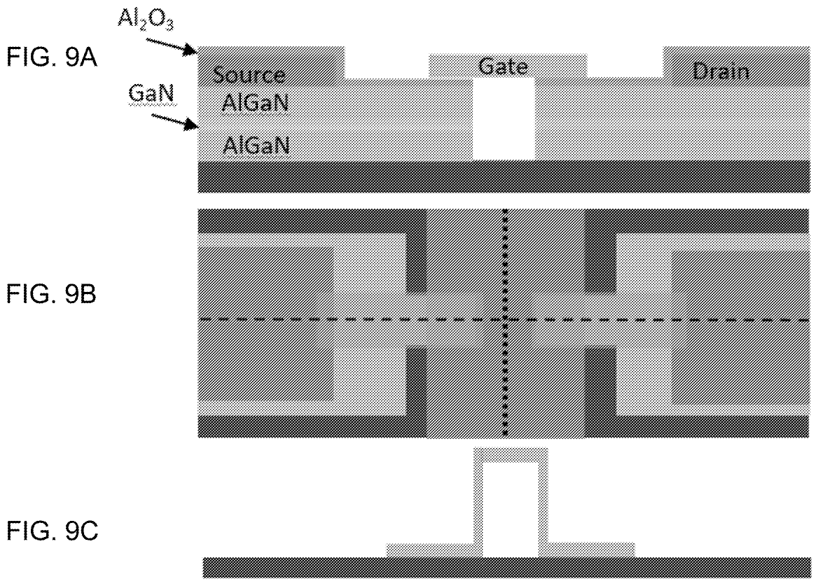

FIGS. 9A-9C illustrate an embodiment having a wrap-around top gate located over the nanogap. FIG. 9A is a sectional side view, FIG. 9B is a top view, and FIG. 9C is a-sectional side view perpendicular to FIG. 9A. The vertical dotted line of FIG. 9B corresponds to the sectional view of FIG. 9C. The horizontal dashed line of FIG. 9B corresponds to the sectional view of FIG. 9A.

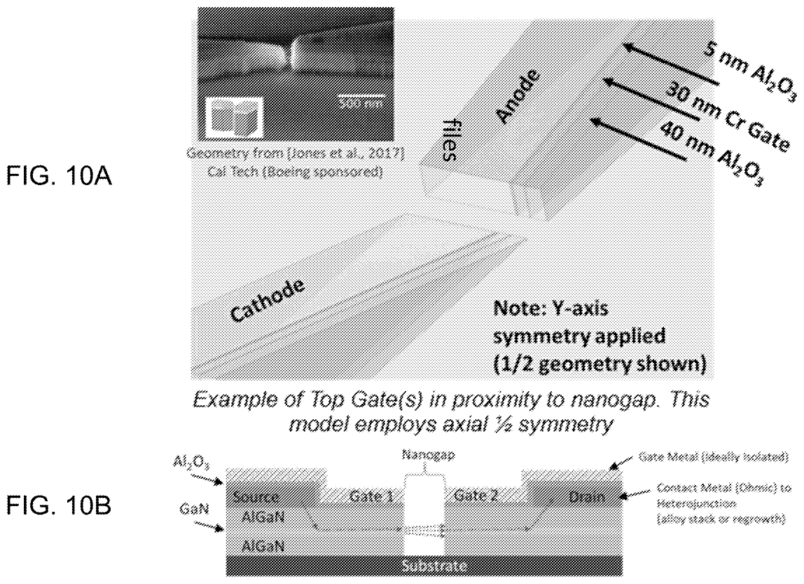

The proposed VacFETs may be used in a lateral field emitter array (LFEA) composed of multiple field emitting cathodes and anodes. For example, FIG. 10A presents a top-down view of a top-gated VacFET with a lateral field emitter array (LFEA) composed of 5 field emitting cathodes and anodes. LFEAs will lead to an increase the total emission current of the device, making it better suited for high power applications. FIG. 10B presents an enlarged view of the source and drain of the VacFET depicted in FIGS. 8A and 10A.

Different top gate configurations are possible for this device relative to the source and drain position as presented in FIGS. 8A-10. One variation is that the source and drain are immediately adjacent to the nanogap on either side and a metal gate is fabricated to be directly coincident on the surface of their connecting ohmic contact metal layers, matching their 2D profile entirely while being electrically isolated from them with an interstitial dielectric layer (FIGS. 8A-8B). This metal-insulator-metal structure may exist on either side of the nanogap, allowing either side to be used as a third terminal gate for 3-terminal operation. This type of operation is distinct from the embodiments of FIGS. 1-6B in that the modulation of the 2DEG would no longer be the primary means of device operation. Instead, device operation would be largely predicated on the modulation of gate-assisted or gate-retarded field emission from the source, depending on which gate is biased. Another variation, as illustrated in FIGS. 9A-9C, has a gate directly central on the surface of the nanogap region, again maintaining electrical isolation form the source and drain with a dielectric insulating barrier layer. The operation of this type of configuration would be a mix of 2DEG carrier modulation and gate-assisted or gate-retarded emission.

The material medium comprising the heterojunction may be readily altered or grown to increase the number of heterojunctions vertically, as presented in FIGS. 8A-8B. Series of stacked heterojunctions have been fabricated for many years and are commonly called superlattices, particularly when spaced closely together. The device operation of the VacFET incorporating a superlattice would be fundamentally the same as that of the single heterojunction device described herein, e.g., FIG. 1. However, a 2DEG layer is formed at each heterojunction, thus the number of 2DEG layers from which vacuum emission would be occurring is increased, thus enabling higher current carrying capacity than a single heterojunction device.

Another variation of the proposed VacFET would use AlGaN/GaN double heterojunction high electron mobility transistors (DH-HEMTs) with an AlGaN buffer layer, which leads to a higher potential barrier at the backside of the 2DEG channel and better carrier confinement. This would reduce the drain leakage current and improves the device breakdown voltage. Furthermore, AlN/AlₓGa₁₋ₓN/AlN DH-HEMTs with thin and strained AlₓGa₁₋ₓN quantum well (with an Aluminum fraction from 0 to 0.74) surrounded by AlN may also be used to build the proposed VacFET. In these devices, the density of the 2DEG can reach level as high as 3.7×10¹³ cm⁻² by changing the Aluminum fraction x while keeping the thickness of the different layers constant. These AlN/AlₓGa₁₋ₓN/AlN DH-HEMTs may be used to build VacFETs for new generations of high-power RF and millimeter-wave devices with larger breakdown voltages suitable for power switching applications.

An array of AlGaN/GaN vacuum diodes may be used as illustrated in FIG. 10B in order to reach higher current levels of operation. An additional top gate may be used to tune the field emission from the array of diodes.

FIGS. 8A-8B illustrate the nanogap extending all the way through the superlattice heterojunction stack to the substrate. However, the nanogap does not need to be that deep. For the superlattice embodiment, the nanogap would need to extend through all the 2DEG layers. The nanogap does not necessarily need to extend all the way to the substrate but must at least bisect all the 2DEG layers. Multiple 2DEG layers may be formed in a heterojunction structure of only 100 nm depth.

Though the embodiment of FIG. 1 and FIGS. 8A-9C each depict top gate VacFETs, there are important distinguishing characteristics between them. Note that in FIG. 1, the source is distant from the nanogap and the gate does not extend to the edge of the nanogap. More importantly, in FIG. 1 the gate is not on top of the source or drain so the gate field is mainly controlling the 2DEG carrier population. In contrast, FIGS. 8A-9C illustrate a gate on the anode or cathode on the right side of the nanogap and the wrap around gate on the left side of the nanogap where the gate is on top and/or wraps around the nanogap region. Both of these are very different from FIG. 1 in both geometry and operation.

Other variations of the VacFETs may include the use of a back gate in FIG. 1, i.e., the arrangement of FIG. 1 with an extra gate potential applied to the back of the substrate. The use of a back gate would help to increase the carrier confinement in the 2DEG and may be used as a solution for short channel effects occurring in scaled down devices, i.e., for VacFETs with shorter top gate or side gate configurations.

VacFET Applications

The proposed VacFETs are based on heterostructures similar to those used to fabricate HEMTs, but their line current density and transconductance levels reach values of several hundreds mA/mm and tens of mS/mm, respectively, which are much larger that the values reported by other groups for their VacFETs.

One advantage of using modified AlGaN/GaN HEMT devices to build VacFETs is that the latter may be implemented for monolithic integration with existing AlGaN/GaN HEMT technologies for high frequency and high power applications. Indeed, GaN based power transistors have been in volume production since 2010. AlGaN/GaN HEMTs are inherently normally ON (depletion mode). Their primary applications were initially focused on the low-voltage and high frequency applications. For the power switching applications, on the other hand, normally OFF (enhancement mode) transistors may be required. The availability of both depletion and enhancement mode AlGaN/GaN HEMTs has led to research interests and efforts in the IC industry for complementary logic applications. Simply swapping the biases on the source and drain contacts (which is equivalent to switching to a VacFET with a nanogap either on the drain or source side of the gate) may lead to devices with current-voltage characteristics associated to depletion-mode or enhancement-mode devices and tunable figures of merit, such as their transconductance. Our simulations show that AlGaN/GaN VacFETs with a nanogap on the source side of the gate may be used as alternatives to p-type enhancement mode AlGaN/GaN HEMTs. The AlGaN/GaN VacFETs with nanogaps proposed here may therefore provide an alternative path for integrating depletion-mode and enhancement-mode HEMT-like devices on the same epitaxial layer. This multi-functionality cannot be achieved with regular HEMTs without changing the thickness of the AlGaN barrier and doping levels in the devices.

Another advantage of the nanogap in the proposed VacFET is that, for regular HEMT devices, fixed defects in the GaN and AlGaN layers may act like traps, offering electron transferring paths between the barrier layer and the substrate, which may generate potential shift and energy band bowing and threshold voltage drift. Therefore, the reduction of defects is mandatory for reducing the charge variations so as to control the threshold voltage instability and reliability. Achieving low defect in III-V nitride layers, requires careful process engineering and optimization. The presence of the nanogap therefore removes at least the problem of defects in that portion of the device, where the motion of carriers is purely ballistic.

The nanogap also may alleviate some of the problems related to current collapse observed in HEMT devices. Current collapse may be induced in the HEMT characteristics as a result of short-term (several hours) DC bias stress. The term “current collapse” is sometimes associated to the reduction in DC current after the application of a high source-drain voltage. The high voltage leads to the injection of hot carriers into regions of the device adjacent to the conducting channel that contains traps. The trapping of these hot carriers leads to a reduction in the drain current that persists as long as the carriers remain trapped. Current collapse reduces the maximum available drain current and increases the knee voltage, thereby limiting the drain current and voltage excursions and leading in a reduced microwave output power.

In the past, two-terminal GaN-based power rectifiers have been demonstrated with low-forward turn-on voltage, low specific on-resistance, and high reverse breakdown voltage.

These devices are indispensable components in high-power electronics applications such as switching mode power supplies and power factor correction circuits. E-beam lithography has been used followed by inductively coupled plasma etching to create a variable nanotrench structure for electric field modulation in AlGaN/GaN HEMT devices. Using this approach, they fabricated lateral nanoscale multi-channel AlGaN/GaN-on-Silicon Schottky barrier diodes (SBDs) with a turn-on voltage as low as 0.61 V and on-resistance of 7.8 Ω-mm. The proposed AlGaN/GaN VacFET with a nanogap on the drain side may also be operated as a tunable SBD with a turn-on voltage of about 1 V and a tunable on-resistance of the order of Ω-mm as V_{GS}. A similar tunability may be reached with the nanogap on the source side. For our VacFETs, their threshold voltage along the V_{DS} may be made much larger by designing the nanogap using a sharp V-shape e-beam cut which would favor current flow from source to drain but would hamper in the opposite direction when the roles of the source and drain are swapped. Therefore, one potential application of the proposed AlGaN/GaN VacFETs with a modified e-beam cut to define the nanogap would be as a tunable power rectifier. Two-terminal power rectifiers with low forward turn-on voltage, low specific on resistance, and high reverse breakdown voltage are indispensable components in high-voltage power electronics applications, where they can be used as switching-mode power supplies and power factor correction circuits. The proposed VacFETs provide alternatives to the various complicated structures which have been fabricated to reduce the turn-on voltage of AlGaN/GaN SBDs, such as the recessed Schottky barrier diode, a silicon carbon nitride cap layer, and an ohmic-grid-Schottky diode.

The I_{DS}-V_{DS} characteristics of the proposed VacFETs are characterized by a threshold voltage slightly below 1 V and a tunable on-resistance above threshold down to about 10 Ω-mm. These characteristics are similar to those of an AlGaN/GaN HEMT with integrated recessed Schottky-drain protection diode. The latter was shown to have an excellent reverse blocking with minor trade-off for the on-state resistance. As mentioned earlier, the reverse blocking of our proposed VacFETs may also be tuned by using a cathode with a sharp tip defined by e-beam lithography. The proposed VacFETs may therefore provide an alternative to AlGaN/GaN HEMTs with an integrated recessed Schottky-drain protection diode and may find applications for high-frequency switching in microwave switch-mode amplifiers.

For the development of low-cost GaN integrated power converters that require both HEMT switches and rectifiers, the combination of AlGaN/GaN VacFETs and regular HEMT devices on the same chip may offer an alternative route for the integration of high-performance power transistors and rectifiers using the same epitaxial wafer. A combination of the as proposed VacFETs and regular HEMTs may therefore provide a low-cost alternative to GaN power integrated circuits. Since the VacFETs described here offer the flexibility to be used both as high-voltage power devices and low-voltage SBDs which may be monolithically integrated easily, they may become important building blocks of GaN smart power technology based on the same AlGaN/GaN epitaxial layer.

Another advantage of the nanogap in the proposed VacFET is that, for regular HEMT devices, fixed defects in the GaN and AlGaN layers can act like traps offering electron transferring paths between the barrier layer and the substrate, which can generate potential shift and energy band bowing and threshold voltage drift. Therefore, the reduction of defects is mandatory for reducing the charge variations so as to control the threshold voltage instability and reliability. Achieving low defect in III-V nitride layers requires careful process engineering and optimization. The presence of the nanogap therefore removes at least the problem of defects in that portion of the device, where the motion of carriers is purely ballistic. When operated at large current densities, the high injection of carriers across the nanogap can lead to self-heating effects and a temperature rise in the proposed VacFET. The proposed VacFETs could provide alternatives to previously proposed plasmonic terahertz detectors for biodetection. In particular, nitride based technologies have been investigated as potential chemical and biological sensors for detection of gases, ions, pH levels, liquids and bio-molecules. In the proposed VacFETs, the presence of adsorbates at the semiconductor channel/nanogap interface will change its work function and affects the tunneling current across the nanogap. The current through the proposed VacFETs was shown to be highly sensitive to the value of the effective work function β_{eff} of the nanogap region.

In the proposed VacFETs, the presence of adsorbates at the semiconductor channel/nanogap interface will change its work function and affects the tunneling current across the nanogap. We have shown that the sensitivity of the current through a VacFET to be proportional to the value of the effective work function Φ_{eff}.

While the present invention has been illustrated by a description of one or more embodiments thereof and while these embodiments have been described in considerable detail, they are not intended to restrict or in any way limit the scope of the appended claims to such detail. Additional advantages and modifications will readily appear to those skilled in the art. The invention in its broader aspects is therefore not limited to the specific details, representative apparatus and method, and illustrative examples shown and described. Accordingly, departures may be made from such details without departing from the scope of the general inventive concept.

What is claimed is:

1. A transistor comprising
a first layer comprising a first material;
a second layer comprising a second material applied directly onto the first layer, the first layer of the first material and the second layer of the second material forming a first heterojunction;
a first 2-dimensional gas (2DEG) layer in the first layer adjacent the first heterojunction, a plane of the 2DEG layer being parallel to the first heterojunction;
a source electrode and a drain electrode fixed on the second layer opposite the first layer;
a nanogap between the source electrode and the drain electrode, the nanogap extending through the first layer and at least partially through the second layer beyond the plane of the 2DEG layer, the nanogap arranged perpendicular to the heterojunction; and
one or more gates arranged adjacent the source electrode.

2. The transistor of claim 1, wherein the nanogap is between about 30-50 nm in width.

3. The transistor of claim 1, wherein the one or more gates are top gates, and the nanogap is formed on one of a drain side and a source side of the one or more top gates.

4. The transistor of claim 1, wherein the one or more gates are side gates.

5. The transistor of claim 1, wherein the first material is Gallium Nitride (GaN) and the second material is (Aluminum Gallium Nitride) AlGaN.

6. The transistor of claim 1, wherein the first and second materials are different and are selected from the list consisting of diamond, SiC (Silicon carbide), BN (Boron Nitride), AlP (Aluminum Phosphide), AlAs (Aluminum Arsenide), GaP (Gallium Phosphide), CdS (Cadmium Sulfide), CdSe (Cadmium Selenide), CdTe (Cadmium Telluride), ZnO (Zinc Oxide), ZnSe (Zinc Selenide), ZnS (Zinc Sulfide), ZnTe (Zinc Telluride), GaSe (Gallium Selenide), β-phase GaO (β-phase Gallium Oxide), and a wide variety of ultrawide bandgap binary and ternary oxides, including aluminum gallium nitride alloys (AlₓGa₁₋ₓN), Indium Gallium Nitride (InₓGa₁₋ₓN), β-phase gallium oxide (β-Ga₂O₃), SnO₂, r-GeO₂, ZnGa₂O₄, MgGa₂O₄, BaSnO₃, SrSnO₃, (La_{0.75}Sr_{0.25})CrO₃, AlₓSc₍₁₋ₓ₎N, Ba₂BiTaO₆, CuBO₂, and (Ir_{0.4}Ga_{0.6})₂O₃.

7. A transistor further comprising
a first layer comprising a first material;
a second layer comprising a second material applied directly onto the first layer, the first layer of the first material and the second layer of the second material forming a first heterojunction;
a first 2-dimensional gas (2DEG) layer in the first layer adjacent the first heterojunction, a plane of the 2DEG layer being parallel to the first heterojunction;
a third layer comprising the first material;
a fourth layer comprising the second material applied directly onto the third layer, the third layer of the first material and the fourth layer of the second material forming a second heterojunction;
a second 2-dimensional gas (2DEG) layer in the third layer adjacent the second heterojunction, a plane of the 2DEG layer being parallel to the second heterojunction;
a source electrode and a drain electrode fixed on the fourth layer opposite the third layer;
a nanogap between the source electrode and the drain electrode, the nanogap extending from the fourth layer into each layer and beyond the plane of each 2DEG layer, the nanogap arranged perpendicular to the first and second heterojunctions; and
one or more gates arranged adjacent the source electrode.

8. A transistor comprising
a first layer comprising a first material;
a second layer comprising a second material applied directly onto the first layer, the first layer of the first material and the second layer of the second material forming a first heterojunction;
a first 2-dimensional gas (2DEG) layer in the first layer adjacent the first heterojunction, a plane of the 2DEG layer being parallel to the first heterojunction;
a third layer comprising the first material or a third material which is different from the first and second materials;
a fourth layer comprising the second material or a fourth material which is different from the first, second, and third materials applied directly onto the third layer, the third layer of the first material and the fourth layer of the second material forming a second heterojunction;
a second 2-dimensional gas (2DEG) layer in the third layer adjacent the second heterojunction, a plane of the 2DEG layer being parallel to the second heterojunction;
a source electrode and a drain electrode fixed on the fourth layer opposite the third layer;
a nanogap between the source electrode and the drain electrode, the nanogap extending from the fourth layer into each layer and beyond the plane of each 2DEG layer, the nanogap arranged perpendicular to the first and second heterojunctions; and
one or more gates arranged adjacent the source electrode.
